(19) United States
(12) Patent Application Publication
(10) Pub. No.: US 2007/0264829 A1
(43) Pub. Date: Nov. 15, 2007

(54) SLURRY AND METHOD FOR CHEMICAL MECHANICAL POLISHING

(75) Inventors: Yong Soo Choi, Seongnam-si (KR); Jae Gon Choi, Pyeongtaek-si (KR); Gyu Hyun Kim, Yongin-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/618,681

(22) Filed: Dec. 29, 2006

(30) Foreign Application Priority Data
May 12, 2006 (KR) 10-2006-0043128
Jul. 3, 2006 (KR) 10-2006-0062212

(51) Int. Cl. H01L 21/461; C03C 15/00; C09K 13/06

(52) U.S. Cl. 438/692; 438/693; 216/89; 252/79.4

(57) ABSTRACT

A chemical mechanical polishing slurry, contains an abrasive dispersed in deionized water and an organic viscosity modifier added to adjust the viscosity of the slurry to within a range of 0.5 to 3.2 cps.

### CROSS-REFERENCE TO RELATED APPLICATIONS

The present application claims priority to Korean patent application Nos. 10-2006-0043128 and 10-2006-62212, filed on May 12, 2006 and Jul. 3, 2006, respectively, which are incorporated herein by reference in their entirety.

### BACKGROUND OF THE INVENTION

The present invention relates to a semiconductor device. More specifically, the present invention relates to chemical mechanical polishing slurry and a chemical mechanical polishing method using the slurry.

A trend toward high integration of semiconductor devices has led to the introduction of chemical mechanical polishing (CMP) to realize uniform flatness of the devices. The chemical mechanical polishing achieves a high degree of planarity by simultaneously undergoing chemical polishing through chemical reactions of a polishing solution. The polishing solution is provided in the form of slurry. Mechanical polishing is provided via the action of a polishing slurry and a polishing pad during manufacture of the semiconductor devices.

The chemical mechanical polishing may be applied to a formation process of device isolation films such as a shallow trench isolation (STI) technique. The chemical mechanical polishing may also be applied to a node isolation process of landing plugs connected between sources and bit lines or between drains and storage nodes of a semiconductor substrate.

FIGS. 1 and 2 are illustrate conventional planarization of a semiconductor device. FIGS. 3 through 6 illustrate conventional node isolation when forming a landing plug.

The STI process is described with reference to FIGS. 1 and 2. A trench is formed within the semiconductor substrate using a mask film pattern including a silicon nitride film. A buried insulating film for embedding the trench is formed. The chemical mechanical polishing is performed and the mask film pattern is removed to isolate active regions and device isolation regions of the semiconductor substrate. When the silicon nitride film is used as a polishing endpoint, it is preferred to ensure that the chemical mechanical polishing achieves a higher polishing selectivity for a silicon oxide film than for the silicon nitride film.

Node isolation of a landing plug is described with reference to FIGS. 3 through 6. Gate stacks are formed on a semiconductor substrate. An interlayer dielectric film is formed for embedding the gate stacks. The interlayer dielectric film is selectively removed to form landing plug contact holes between the gate stacks. A conductive material layer is formed for embedding the landing plug contact holes. The chemical mechanical polishing is performed to form an isolated landing plug. Since a hard mask film of the gate stack serves as a polishing endpoint, it is preferred to ensure that the chemical mechanical polishing achieves a higher polishing selectivity for the conductive material layer than for the hard mask layer.

When performing the chemical mechanical polishing process, a polishing rate may vary from region to region or a high-polishing selectivity may not be achieved. Thus, a non-uniformity of polishing may result in various problems. For example, a higher removal rate at a central region of a wafer than at an edge region thereof may lead to a lower thickness of the remaining STI film or conductive material layer in the central region of the wafer. As a result, a difference of about 500 to 1000 Å in the polishing amount may occur between the central and edge regions of the wafer.

Referring to FIG. 5, a non-uniformity of the polishing may decrease the value of a critical dimension (CD)of the landing plug node isolation for the edge region of the wafer. Such non-uniformity of the polishing may worsen when using a polishing solution containing a high-selectivity slurry such as a ceria (CeO₂) slurry.

When the chemical mechanical polishing process is performed on the central region of the wafer or semiconductor substrate, a buried insulating film 14 (see FIG. 1) is formed to a desired thickness in the central region of the wafer or semiconductor substrate 10. A landing plug 48 (see FIG. 4) provides node isolation. However, the edge region of the wafer (see FIG. 2) undesirably retains a buried insulating film 14′ on a mask film pattern 12 including a nitride film. When performing the node isolation process of the landing plug, the edge region of the wafer (see FIG. 4) does not undergo the polishing to a hard mask film 42 which is a polishing endpoint. Therefore, a conductive material layer 46 may remain on an interlayer dielectric film 44 resulting in a failure of node isolation of the landing plug.

Upon removing mask film patterns 12, the STI process may be defective because the mask film patterns 12 are not sufficiently and smoothly removed due to the remaining buried insulating film 14′. In addition, the varied thickness of the buried insulating film 14′ at the corresponding regions may cause defects upon subsequent formation of a transistor device.

During the isolation process of the landing plug, the presence of the conductive material layer 46 remaining on the interlayer dielectric film 44 may result in incomplete isolation of contacts and, consequently, the formation of bridges (A) as shown in FIG. 6.

In order to overcome such problems, the central region of the wafer is excessively polished. The mask layer patterns undesirably undergo excessive erosion or removal resulting in weak points. The hard mask film may also undergo an excessive removal leading to defects in self-aligned contacts). Therefore, operation characteristics of the device may be adversely impacted due to the weak points of the semiconductor substrate resulting from excessive polishing of the central region of the wafer.

### SUMMARY OF THE INVENTION

Embodiments of the present invention provide a chemical mechanical polishing slurry, comprising a slurry containing an abrasive dispersed in deionized water and an organic viscosity modifier added to adjust the viscosity of the slurry to within a range of 0.5 to 3.2 cps.

The viscosity modifier used in the present invention may be a fatty acid ester containing a polyhydric alcohol, preferably glycerol. Alternatively, the viscosity modifier is preferably a fatty acid ester including polyoxyethylene sorbitan.

Examples of the abrasive used in the present invention include alumina (Al₂O₃) abrasive particles or fumed alumina abrasive particles. Preferably, ceria abrasive particles are used.

The viscosity modifier may be preferably added in an amount of up to 10 wt % relative to the weight of the slurry.

The viscosity modifier may be added in an amount such that the viscosity of the slurry is adjusted to a range of at least 1.21 cps (or 1.2 cps), preferably 1.21 to 2.14 cps (or 1.2 to 2.2), more preferably 1.43 to 2.14 cps (or 1.4 to 2.2), particularly preferably about 1.72 cps (or 1.7, or 1.7 to 1.75).

In accordance with another aspect of the present invention, a polishing method using the chemical mechanical polishing (CMP) slurry according to the present invention is provided. The method comprises providing a polishing-target film of the wafer positioned. A polishing pad is provided a slurry that contains an abrasive dispersed in deionized water and an organic viscosity modifier added to adjust a viscosity of the slurry to within a range of 0.5 to 3.2 cps. The polishing-target film is polished using the polishing pad.

Preferably, the polishing-target film is an oxide film.

The viscosity modifier used in the present invention is a fatty acid ester containing a polyhydric alcohol, preferably glycerol. Alternatively, the viscosity modifier is preferably a fatty acid ester including polyoxyethylene sorbitan.

The viscosity modifier may be preferably used in an amount of up to 10 wt % relative to the weight of the slurry.

The viscosity modifier may be added in an amount such that the viscosity of the slurry is adjusted to a range of at least 1.21 cps, preferably 1.21 to 2.14 cps, more preferably 1.43 to 2.14 cps, particularly preferably about 1.72 cps.

In accordance with a further aspect of the present invention, a polishing method using the chemical mechanical polishing slurry according to the present invention is provided. A silicon nitride layer is formed over a semiconductor substrate. A portion of the semiconductor substrate exposed to the silicon nitride layer is selectively etched to form a trench. The trench is filled with a silicon oxide film. The semiconductor substrate is polished the silicon oxide film to expose a surface of the silicon nitride layer using a polishing pad is provided with a slurry containing an abrasive dispersed in deionized water and an organic viscosity modifier added to adjust the viscosity of the slurry to within a range of 0.5 to 3.2 cps. The silicon oxide film is polished using the polishing pad to expose the surface of the silicon nitride film.

Preferably, the polishing-target film is an oxide film.

The viscosity modifier used in the present invention is a fatty acid ester containing a polyhydric alcohol, preferably glycerol. In addition, the viscosity modifier is preferably a fatty acid ester including polyoxyethylene sorbitan.

Examples of the abrasive used in the present invention include alumina (Al₂O₃) abrasive particles or fumed alumina abrasive particles. Preferably, ceria abrasive particles are used.

The viscosity modifier may be preferably added in an amount of up to 10 wt % relative to the weight of the slurry.

The viscosity modifier may be added in an amount such that the viscosity of the slurry is adjusted to a range of at least 1.21 cps, preferably 1.21 to 2.14 cps, more preferably 1.43 to 2.14 cps, particularly preferably about 1.72 cps.

In accordance with yet another aspect of the present invention, a polishing method using the chemical mechanical polishing slurry according to the present invention is provided. A gate stack is formed over a semiconductor substrate. A dielectric layer is formed on the surface of the semiconductor substrate. A mask pattern is formed to expose a portion of the dielectric film. The dielectric film is etched using the mask pattern, thereby forming a landing plug contact hole including a storage node contact region and a bit line contact region. A conductive material layer is formed to fill the exposed region of the semiconductor substrate and the landing plug contact hole. The semiconductor substrate is provided to chemical mechanical polishing (CMP) equipment such that the conductive material layer of the substrate is positioned opposite a polishing pad of the CMP equipment. The polishing pad is provided with a slurry containing an abrasive dispersed in deionized water and an organic viscosity modifier added to adjust the viscosity of the slurry to within a range of 0.5 to 3.2 cps. The conductive material layer is polished using the polishing pad to expose the top surface of the gate stack to thereby form a landing plug.

Preferably, the conductive material layer includes a polycrystalline silicon layer.

The viscosity modifier used in the present invention is a fatty acid ester containing a polyhydric alcohol. Preferably, the fatty acid ester viscosity modifier contains glycerol. Alternatively, the viscosity modifier is preferably a fatty acid ester including polyoxyethylene sorbitan.

Preferably, examples of the abrasive used in the present invention include ceria (CeO₂) abrasive particles, alumina (Al₂O₃) abrasive particles and fumed alumina abrasive particles.

The viscosity modifier may be preferably added in an amount of up to 10 wt % relative to the weight of the slurry.

### BRIEF DESCRIPTION OF THE DRAWINGS

The above and other embodiments, features and other advantages of the present invention will be more clearly understood from the following detailed description taken in conjunction with the accompanying drawings, in which:

FIGS. 1 and 2 illustrate conventional planarization of a semiconductor device;

FIGS. 3 through 6 illustrate conventional node isolation when forming a landing plug;

FIG. 7 is a graph illustrating a relationship between a friction coefficient and a Hersey number;

FIG. 8 is a graph illustrating a relationship between the Hersey number and the friction coefficient when performing a chemical mechanical polishing process;

FIG. 9 illustrates changes in a shear rate and viscosity with respect to a varying thickness of a polishing slurry layer;

FIG. 10 is a graph illustrating changes in viscosity with respect to a varying shear rate;

FIG. 11 is a graph showing the measurement results of polishing uniformity when using a chemical mechanical polishing slurry according to the present invention; and

FIGS. 12 through 18 illustrate chemical mechanical polishing using a slurry according to the present invention.

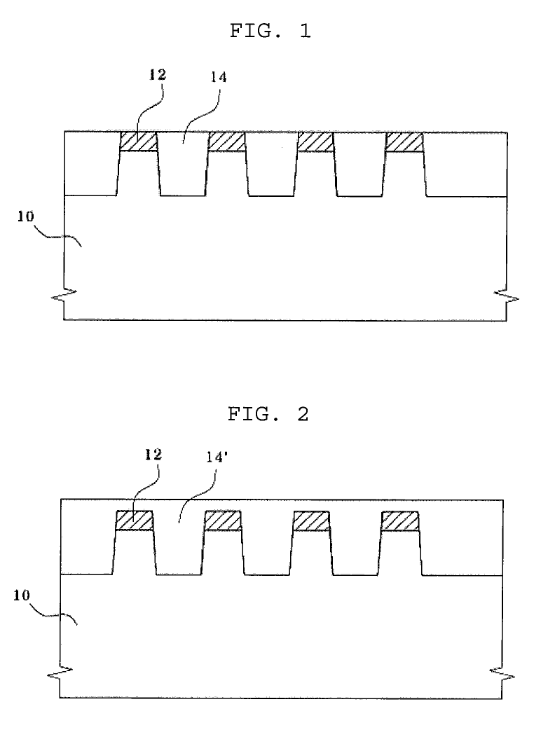

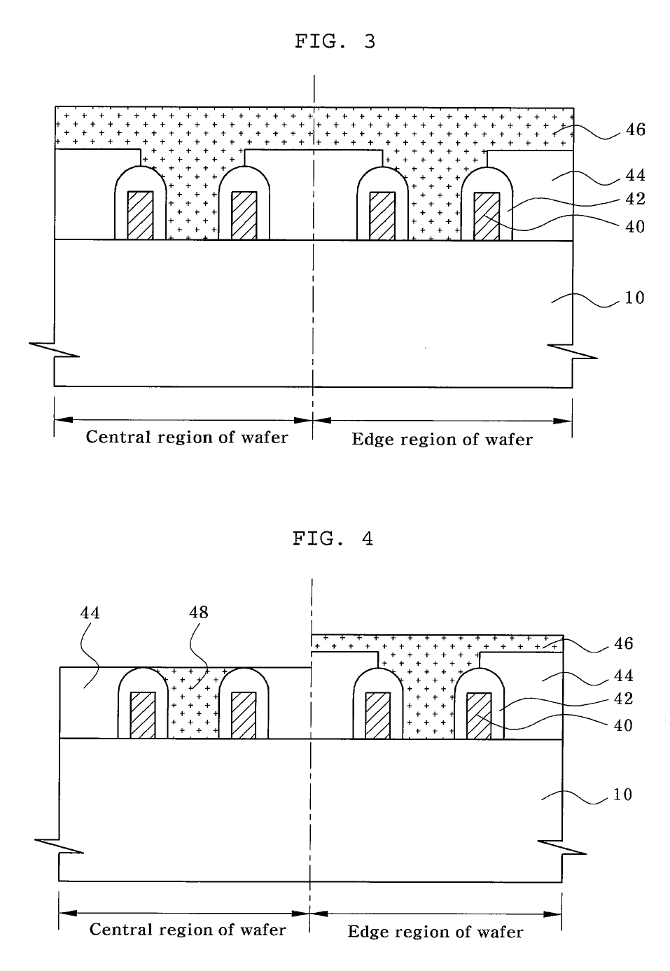

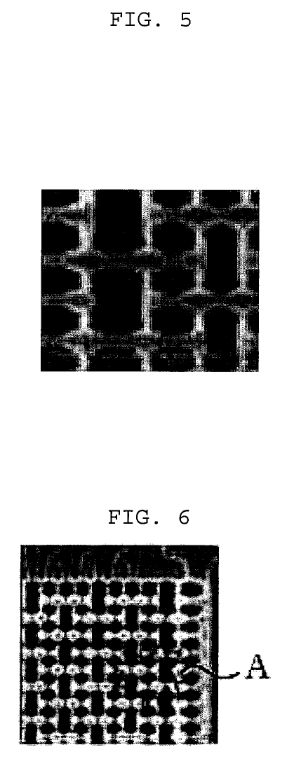

### DESCRIPTION OF THE SPECIFIC EMBODIMENTS

The present invention will now be described more fully with reference to the accompanying drawings, in which specific embodiments of the invention are shown. The present invention may, however, be embodied in different forms and should not be construed as being limited to the embodiments set forth herein. In the drawings, thicknesses of various layers and regions are exaggerated for clarity. Like numbers refer to like elements throughout the specification and drawings.

In an embodiment of the invention, a slurry composition is provided for achieving more uniform chemical mechanical polishing, and a chemical mechanical polishing method using the slurry. In particular, a polishing method is provided which achieves a higher selectivity for a mask film pattern including a silicon nitride film and a polishing-target film (e.g., a silicon oxide film) by preferably using a slurry containing ceria (CeO₂) abrasive particles.

In another embodiment of the invention, a polishing method is provided which achieves a higher selectivity for an oxide film and a polishing-target film (e.g., a polycrystalline silicon layer) by preferably using a slurry containing ceria (CeO₂) abrasive particles.

In a further embodiment of the invention, there is provided a technique of controlling a degree of external flow or retention of the polishing slurry by the adjustment of a slurry viscosity. The slurry is supplied to the central and edge regions of the wafer to improve the polishing uniformity during a polishing process.

An external discharge amount of the slurry may vary depending upon hydrostatic pressure corresponding to a force applied to a polishing pad in a top-to-bottom direction and to a shear rate of the slurry. As a result, the thickness of the slurry present between a polishing-target film and the polishing pad may exhibit some variations depending on the corresponding regions. Such variations in the thickness of the slurry according to the corresponding regions may lead to an increase in polishing non-uniformity. In order to prevent polishing non-uniformity, a technique is provided of increasing the polishing uniformity by maintaining and controlling the thickness of the slurry between the polishing-target film and the polishing pad via the adjustment and control of the slurry viscosity.

The thickness of the slurry may exhibit a difference between the central region and an edge region of the wafer, depending on a contact mode of two objects rotating during the polishing process (e.g., a contact mode of two rotating objects under the slurry between the polishing-target film and the polishing pad).

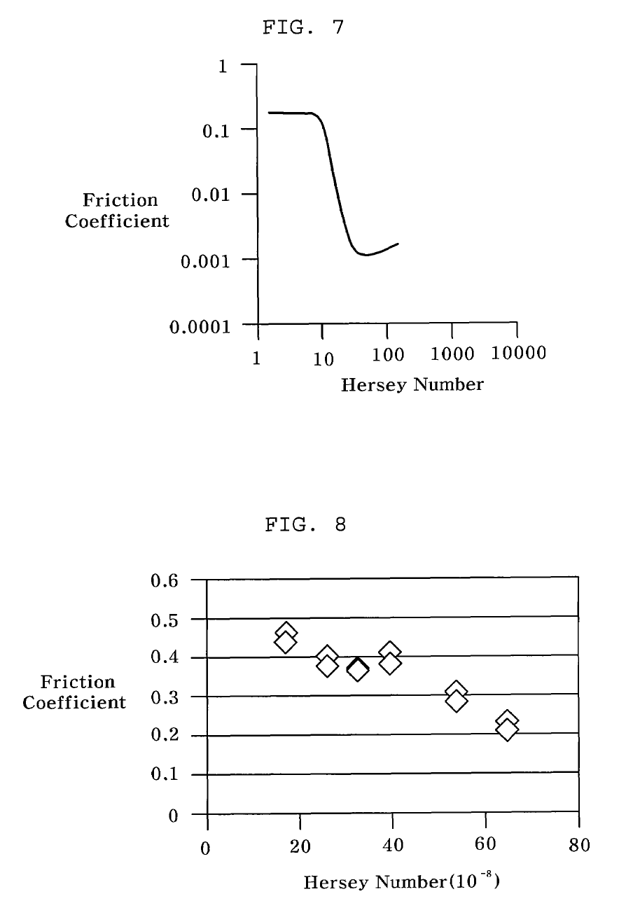

FIG. 7 is a graph illustrating a relationship between a friction coefficient and a Hersey number. FIG. 8 is a graph illustrating a relationship between the Hersey number and the friction coefficient when performing a chemical mechanical polishing process.

Referring to FIG. 7, an increase in the Hersey number leads to a decrease in the friction coefficient. The Hersey number is a coefficient of a relationship between a lubricant and pressure under bearing operation conditions. The Hersey number is defined as a value calculated by the product of a velocity of a moving object and a viscosity of a fluid present between two moving objects, and divided by the pressure applied to the object. The Hersey number is proportional to the thickness of the fluid present between the two moving objects. In other words, the conditions of bringing about an increase of the Hersey number result in an increased thickness of the fluid layer present between two moving objects, which consequently leads to a decreased friction coefficient.

Applying an interrelationship between the friction coefficient and Hersey number to a practical chemical mechanical polishing process, the friction coefficient decreases as the Hersey number increases, as shown in FIG. 8. A contact mode between a polishing-target film and a polishing pad is a partial contact (e.g., a mixed solid-fluid contact). The contact mode may be direct contact or indirect contact depending on various positions of the polishing-target film and the polishing pad.

When the polishing-target film is in direct contact with the polishing pad, the polishing mechanism is primarily affected by mechanical factors. Under hydrodynamic lubrication conditions where the polishing-target film and the polishing pad are not in the direct contact, the polishing mechanism may be greatly affected by chemical factors such as erosion, rather than by mechanical factors.

If the Hersey number is increased during the chemical mechanical polishing process, it is possible to further increase the thickness of the polishing slurry layer present between the polishing-target film and the polishing pad. It is therefore possible to achieve a reduction of the friction coefficient, and it is also possible to achieve a relative reduction of mechanical polishing factors which are considered to be main causes of the polishing non-uniformity. As a result, an increase of the polishing uniformity can be more effectively realized throughout the entire region of the wafer.

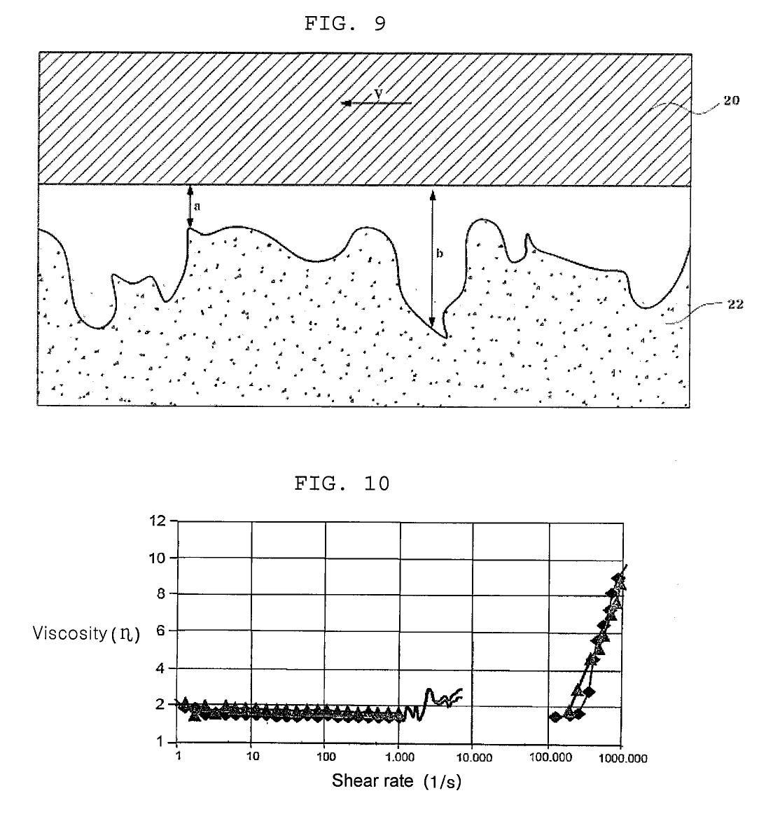

FIG. 9 is a view showing changes in a shear rate and a viscosity with respect to a varying thickness of a polishing slurry layer. FIG. 10 is a graph showing changes in a viscosity with respect to a varying shear rate.

As shown in FIG. 9, the distance between a polishing-target film 20 and a polishing pad 22 during the polishing process may be not constant. For this reason, a difference in a shear rate may occur which corresponds to a flow of the slurry present between two materials. For example, when the polishing-target film 20 is moved (e.g., rotated) at a velocity (V) of 1 m/sec, region “a” having a distance of 1 μm between the polishing-target film 20 and the polishing pad 22 may have a shear rate of 1,000,000 1/sec. Region “b” having a distance of 2.5 μm between the polishing-target film 20 and the polishing pad 22 may have a shear rate of 400,000 1/sec.

A narrower distance between the polishing-target film 20 and the polishing pad 22 results in a higher shear rate. However, as shown in FIG. 10, in the region having a relatively high shear rate of more than 1,000,000 1/sec where a real polishing process takes place, the viscosity of the slurry undergoes a sharp change with respect to the shear rate. Such a sharp increase of the slurry viscosity leads to a significant decrease in the fluidity or lubricability of the slurry while leading to a relatively high prevalence of mechanical polishing action.

As a result, the region showing the prevalence of mechanical polishing factors undergoes a relatively high-speed polishing; whereas, the region showing relatively low mechanical polishing undergoes a relatively low-speed polishing. Such a difference of the polishing rate may result in a non-uniformity of the polishing, which is accompanied by a substantial difference in a thickness of the remaining films between the center and an edge of the wafer.

Conventional polishing techniques suffer from a higher polishing rate in the edge region of the wafer as compared to the central region of the wafer. As discussed above, such an event results from a relatively narrowed distance between the wafer and polishing pad due to the pressure applied to the central region of the wafer, and hence a sharp increase of the viscosity of the practical slurry during the polishing process. In order to cope with such a non-uniformity of polishing, it may be first considered to reduce the pressure applied to the polishing process and the rotation speed. Considering the correlation with the Hersey number, the present invention reduces the friction coefficient by increasing the viscosity of the polishing slurry.

The present invention adjusts the viscosity of the polishing slurry between the polishing-target film and the polishing pad to increase the Hersey number and, consequently, to decrease the friction coefficient. Decreasing the friction coefficient increases the thickness of the polishing slurry film maintained during the polishing process to control a removal rate of the polishing-target film, thereby controlling profiles of the polishing-target film.

FIG. 11 is a graph showing the measurement results of a polishing uniformity when using a chemical mechanical polishing slurry according to the present invention.

In order to increase the viscosity of the slurry, the chemical mechanical polishing slurry according to the present invention comprises an abrasive containing, preferably, ceria (CeO₂) abrasive particles, deionized water (DIW) and a viscosity modifier which increases the viscosity of the slurry to a value higher than the intrinsic viscosity of the deionized water. The viscosity modifier is added to the slurry and serves to further increase the viscosity of the slurry. The viscosity modifier may be an organic material (e.g., composed of a fatty acid ester containing a polyhydric alcohol). Such an organic material is preferred to have chemical properties that do not adversely impact the acidity (pH) of the slurry. As the preferred organic material, glycerol may be used. Alternatively, the viscosity modifier may be an organic material composed of a fatty acid ester including polyoxyethylene sorbitan. A chemical structure of such a polyoxyethylene sorbitan is represented by Formula (or Representation) I below:

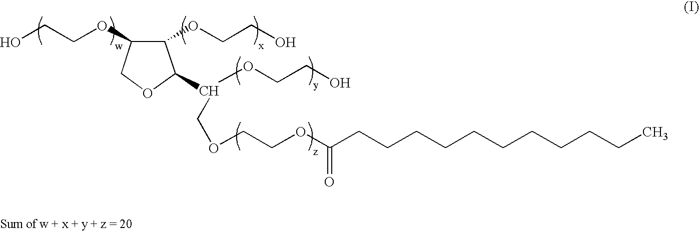

In Formula I, each w, x, y and z represents a molar fraction, and the sum of the molar fraction is preferably smaller than 20.

Examples of the abrasive may include alumina (Al₂O₃) abrasive particles, fumed aluminum oxide abrasive particles and ceria (CeO₂) abrasive particles. It is preferred to use the ceria (CeO₂) abrasive in order to achieve a higher selectivity for a silicon nitride film. The content of the viscosity modifier is preferred to be maintained within a range of up to 10 wt % based on the total weight of the slurry. A ratio of the abrasive, deionized water and viscosity modifier in the chemical mechanical polishing slurry of the present invention is in the range of about 1:3:3 (v/v). In addition to the above-mentioned components, the slurry may further include other additives such as a pH-adjusting agent, a surfactant and the like. Preferably, the viscosity modifier is added in an amount of 0.1 to 15% by volume, relative to deionized water.

The viscosity modifier may be added in such an amount that the viscosity of the slurry is in a range of 0.5 to 3.2 cps. Preferably, the viscosity modifier is added in such an amount that the viscosity of the slurry is in a range of 1.21 to 2.14 cps. The viscosity modifier is preferably added such that the viscosity of the slurry does not exceed 3.2 cps. In addition, the chemical mechanical polishing process using such a polishing slurry is preferably carried out at 30 to 110 rpm under pressure of 2 to 7 psi.

After the viscosity of the slurry is adjusted using such a viscosity modifier, an amount of an oxide film, removed upon performing the chemical mechanical polishing process, is measured. FIG. 11 shows the measurement results. The chemical mechanical polishing process was carried out at several predetermined viscosities of the slurry. In addition, the polishing slurry was prepared using the ceria (CeO₂) abrasive, deionized water (DIW) and a glycerol viscosity modifier. A volume ratio of slurry components was set to 1:3:3. Various samples were prepared for different viscosities of the polishing slurry and, as in the formation of a shallow trench isolation device, the polishing process was performed on a silicon oxide film (e.g. a PETEOS film) using a silicon nitride as a mask film (or a polishing endpoint).

Referring to FIG. 11, the polishing-target film was polished to a uniform thickness of 1500 to 2000 Å. The polishing-target film was removed from the center and edge of the wafer at the viscosity of the polishing slurry ranging from 1.21 to 2.14 cps.

FIG. 11 shows the data measured using slurry viscosities of 1.21 cps (A), 1.43 cps (B), 1.72 cps (C) and 2.14 cps (D). When the chemical mechanical polishing process was performed while maintaining the viscosity of the slurry at 1.21 cps, Data A shows a significant non-uniformity of polishing between the center and an edge of the wafer. If the slurry viscosity decreased below 1.21 cps, the central region of the wafer undergoes a high speed removal resulting in worsening of the polishing non-uniformity. These results were therefore not presented.

Data C was obtained by performing the chemical mechanical polishing process while maintaining the slurry viscosity at 1.72 cps. Data C was measured to show the highest uniformity of polishing. When the slurry viscosity was maintained in the range of 1.43 to 1.72 cps, the chemical mechanical polishing uniformity increased.

Data D was obtained by polishing while maintaining the slurry viscosity at 2.14 cps. Data D showed an insignificant chemical mechanical polishing non-uniformity between the center and edge of the wafer. If the viscosity of the slurry is higher than 2.14 cps, the non-uniformity of polishing is substantially high, resulting in deterioration of polishing uniformity which makes it difficult to apply the slurry to practical processes. When the slurry viscosity of the slurry containing ceria (CeO₂) abrasive particles is higher than 3.2 cps, taking into consideration the data results of FIG. 11, it is difficult to obtain the polishing uniformity as shown in the slurry viscosity of 1.21 to 2.14 cps.

A chemical mechanical polishing method using the above-mentioned chemical mechanical polishing slurry will now be described with reference to the accompanying drawings.

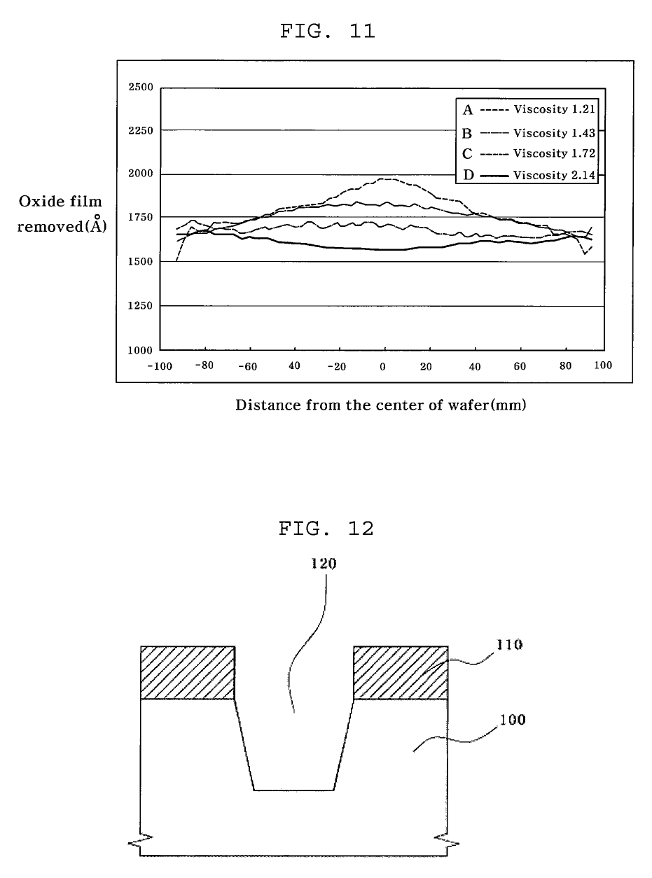

FIGS. 12 through 18 are illustrate chemical mechanical polishing using the chemical mechanical polishing slurry according to the present invention.

FIGS. 12 through 14 illustrate chemical mechanical polishing using the chemical mechanical polishing slurry when forming a trench of a semiconductor device.

Referring to FIG. 12, a trench 120 is formed within a semiconductor substrate 100. A mask film pattern 110 including a nitride film, which defines a trench-forming region, is formed on the semiconductor substrate 100. Using the mask film pattern 110, a trench 120 of a predetermined depth is formed within the semiconductor substrate 100. The mask film pattern 110 may have a bilayer structure composed of an oxide film and a nitride film. Although not shown in FIG. 12, a side wall oxide film, a liner nitride film and a liner oxide film may be sequentially formed on the trench 120.

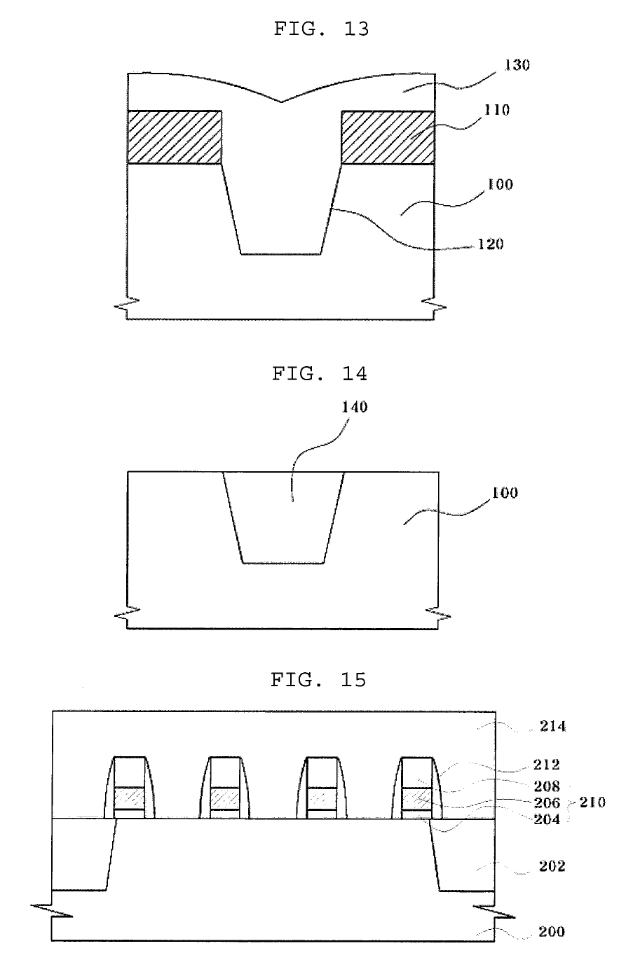

Referring to FIG. 13, a buried insulating film 130 for embedding the trench 120 is formed. In order to embed the trench 120 having a narrow margin, the buried insulating film 130 may be formed by repeatedly embedding, etching and embedding the inside of the trench 120 up to a predetermined thickness, i.e., using a deposition-etch-deposition process or a deposition-etch-deposition-etch-deposition process. The buried insulating film 130 is preferably formed of an oxide film (e.g., a high density plasma oxide film or a plasma enhanced TEOS oxide film).

Referring to FIG. 14, the semiconductor substrate 100 having the buried insulating film 130 formed thereon is positioned opposite a polishing pad (not shown) of chemical mechanical polishing equipment. A slurry is supplied to the polishing pad. The slurry comprises an abrasive containing ceria (CeO₂) abrasive particles, deionized water (DIW) and a viscosity modifier. The viscosity of the slurry is adjusted to within the range of 0.5 to 3.2 cps via the viscosity modifier. The buried insulating film 130 is subjected to the chemical mechanical polishing process using the slurry. The mask film pattern 110 is removed to form a trench isolation film 140. The abrasive may employ a slurry containing alumina (Al₂O₃) abrasive particles, fumed alumina abrasive particles or ceria (CeO₂) abrasive particles. It is preferred to use a slurry containing ceria (CeO₂) abrasive particles to achieve a high selectivity for a nitride film and an oxide film.

The viscosity modifier used herein is added to adjust the viscosity of the slurry. The viscosity modifier is an organic material composed of a fatty acid ester containing a polyhydric alcohol. Preferably, glycerol is used. Alternatively, the viscosity modifier may also employ an organic material composed of a fatty acid ester including polyoxyethylene sorbitan.

The content of the viscosity modifier is preferred to be maintained within an amount of 10 wt % of the total slurry. A ratio of the abrasive, deionized water (DIW) and viscosity modifier in the chemical mechanical polishing slurry of the present invention is in the range of about 1:3:3 (v/v). In addition to the above-mentioned components, the slurry may further include other additives such as a pH-adjusting agent, a surfactant and the like.

An amount of the oxide film was removed when the chemical mechanical polishing process was performed on the oxide film while the slurry viscosity was modified using the viscosity modifier. As shown in FIG. 11, the polishing-target film was removed from the center and edge of the wafer at the viscosity of the polishing slurry ranging from 1.21 to 2.14 cps. The polishing-target film was then polished to a uniform thickness of 1500 to 2000 Å.

FIG. 11 shows the data measured using slurry viscosities of 1.21 cps (A), 1.43 cps (B), 1.72 cps (C) and 2.14 cps (D). Data A, obtained when the chemical mechanical polishing process was carried out while maintaining the viscosity of the slurry at 1.21 cps, shows a relative non-uniformity of polishing between the center and an edge of the wafer. Therefore, if the slurry viscosity decreases below 1.21 cps, a rapid removal occurs at the center of the wafer, resulting in worsening of the polishing non-uniformity. These results were therefore not presented.

When the chemical mechanical polishing process was carried out while maintaining the slurry viscosity at 1.72 cps, Data C showed the highest uniformity of polishing. When the slurry viscosity was maintained at around 1.72 cps (e.g., in the range of 1.43 to 1.72 cps), the chemical mechanical polishing uniformity increases.

Data D, obtained during polishing while maintaining the slurry viscosity at 2.14 cps, showed a relative non-uniformity of polishing between the center and an edge of the wafer. If the viscosity of the slurry is higher than 2.14 cps, the uniformity of polishing deteriorates. Therefore, when the viscosity of the slurry containing ceria (CeO₂) abrasive particles is higher than 3.2 cps, in consideration of the data results of FIG. 11, it is difficult to obtain the polishing uniformity as shown in the slurry viscosity range of 1.21 to 2.14 cps.

When chemical mechanical polishing is performed using the slurry having such a viscosity range, the friction coefficient between the polishing-target film and the polishing pad is decreased. A thickness of the slurry film present between two materials under friction is controlled to a constant thickness, which, consequently, can control a removal rate of the polishing-target film to form uniform polishing profiles.

FIGS. 15 through 18 illustrate chemical mechanical polishing using the chemical mechanical polishing slurry according to the present invention, when forming a landing plug.

Referring to FIG. 15, gate stacks 210 are formed over a semiconductor substrate 200 having active regions defined by device isolation films 202. Spacer films 212 are formed on both sides of the gate stacks 210. Each gate stack 210 is comprised of a gate insulating film 204, a gate conductive film 206 and a gate hard mask film 208. An interlayer dielectric film 214 for embedding the gate stacks 210 is formed on the surface of the semiconductor substrate 200. The dielectric layer 214 may be formed of an oxide film or a silicon oxide film.

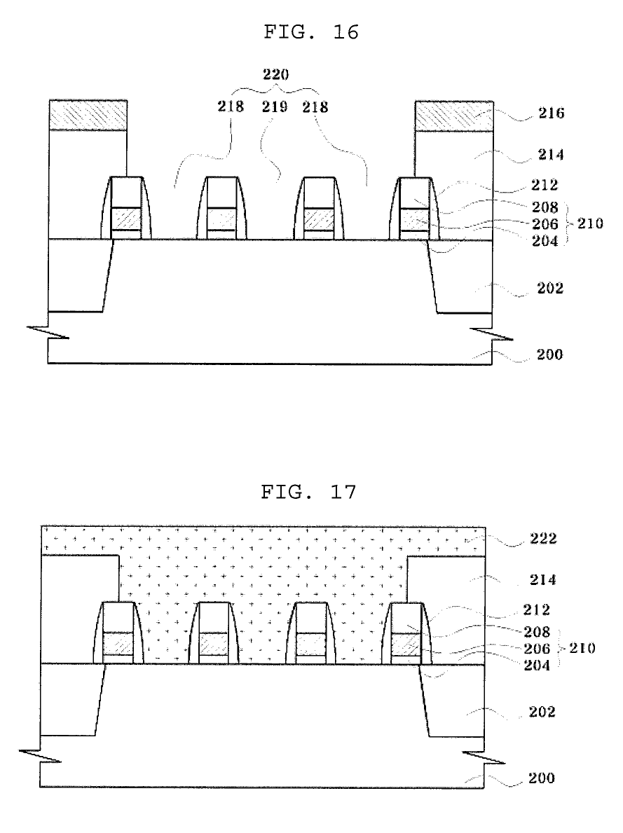

Referring to FIG. 16, hard mask film patterns 216 for selective exposure of the dielectric layer 214 are formed on the semiconductor substrate 200.

Specifically, a nitride film for a hard mask, serving as a hard mask film upon the formation of landing plug contact holes, is formed on the dielectric layer 214. A photoresist film is applied and patterned on the nitride film for a hard mask, thereby forming a photoresist film pattern (not shown) to expose regions in which landing plug contact holes will be formed. Using the photoresist film pattern as a mask, the nitride film for a hard mask is etched to form hard mask film patterns 216 which selectively expose the interlayer dielectric film 214. The photoresist film pattern is then removed.

Using the hard mask film patterns 216 as an etch mask, the dielectric layer 214 between gate stacks 210 is removed to form landing plug contact holes 220 which selectively expose active regions of the semiconductor substrate 200. The hard mask film patterns 216 are then removed. Each individual landing plug contact hole 220 is comprised of storage node contact regions 218 subsequently connected to storage nodes and a bit line contact region 219 subsequently connected to a bit line.

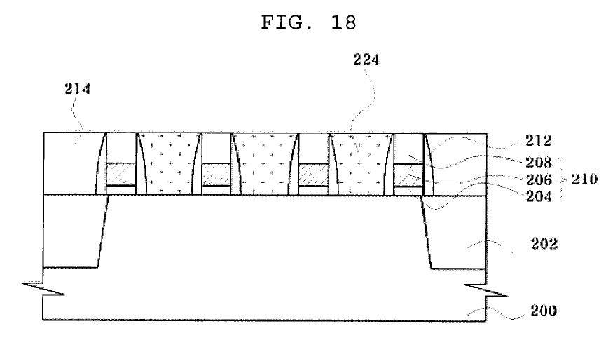

Referring to FIG. 17, a conductive material layer 222 is deposited to ensure that the exposed surface of the semiconductor substrate 200 is embedded. The conductive material layer 222 may be formed of a polycrystalline silicon layer.

Referring to FIG. 18, discrete landing plugs 224 are formed between the gate stacks 210.

Specifically, the semiconductor substrate 200 having the conductive material layer 222 deposited thereon is provided to chemical mechanical polishing equipment such that the conductive material layer 222 is positioned opposite to the polishing pad of the chemical mechanical polishing equipment. A slurry, which contains an abrasive dispersed in deionized water and an organic viscosity modifier added to adjust the viscosity of the slurry to within a range of 0.5 to 3.2 cps, is supplied to the polishing pad. The conductive material layer 222 is polished until the surface of the gate hard mask film 208 of the gate stacks 210 is exposed, thereby forming discrete landing plugs 224.

The abrasive may employ a slurry containing alumina (Al₂O₃) abrasive particles, fumed alumina abrasive particles or ceria (CeO₂) abrasive particles. It is preferred to use a slurry containing ceria (CeO₂) abrasive particles to achieve a high selectivity for the oxide film and polycrystalline silicon film.

The viscosity modifier is added to adjust the viscosity of the slurry. The viscosity modifier is an organic material composed of a fatty acid ester containing a polyhydric alcohol. Preferably, glycerol is used. The content of the viscosity modifier is preferred to be maintained within an amount of 10 wt % of the total slurry. A ratio of the abrasive, deionized water (DIW) and viscosity modifier in the chemical mechanical polishing (CMP) slurry of the present invention is in the range of about 1:3:3 (v/v). In addition to the above-mentioned components, the slurry may further include other additives such as a pH-adjusting agent, a surfactant and the like. Alternatively, the viscosity modifier may be an organic material composed of a fatty acid ester including polyoxyethylene sorbitan.

When chemical mechanical polishing is performed using the slurry having such a viscosity range, the friction coefficient between the polishing-target film (e.g., the conductive material layer 222) and the polishing pad is decreased. A thickness of the slurry film present between two materials subjected to friction is controlled to a constant thickness, which, in turn, controls a removal rate of the polishing-target film to form uniform polishing profiles.

The present invention prevents the formation of bridges due to incomplete isolation between landing plugs, and also prevents the formation of defective self-aligned contacts (SACS) resulting from an excessive removal of the hard mask film.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A chemical mechanical polishing slurry, comprising:
a slurry containing an abrasive dispersed in deionized water; and
an organic viscosity modifier added to adjust the viscosity of the slurry to within a range of 0.5 to 3.2 cps.

2. The slurry according to claim 1, wherein the viscosity modifier is a fatty acid ester containing a polyhydric alcohol.

3. The slurry according to claim 2, wherein the fatty acid ester viscosity modifier contains glycerol.

4. The slurry according to claim 1, wherein the viscosity modifier is a fatty acid ester including polyoxyethylene sorbitan.

5. The slurry according to claim 1, wherein the abrasive includes ceria (CeO₂) abrasive particles.

6. The slurry according to claim 1, wherein the abrasive includes one of: alumina (Al₂O₃) abrasive particles, fumed alumina abrasive particles, or both.

7. The slurry according to claim 1, wherein the viscosity modifier is added in an amount of up to 10 wt % relative to the weight of the slurry.

8. The slurry according to claim 1, wherein the viscosity modifier is added in an amount such that the viscosity of the slurry is adjusted to at least 1.2 cps.

9. The slurry according to claim 1, wherein the viscosity modifier is added in an amount such that the viscosity of the slurry is adjusted to within a range of 1.2 to 2.2 cps.

10. The slurry according to claim 1, wherein the viscosity modifier is added in an amount such that the viscosity of the slurry is adjusted to within a range of 1.4 to 2.2 cps.

11. The slurry according to claim 1, wherein the viscosity modifier is added in an amount such that the viscosity of the slurry is adjusted to approximately 1.7 cps.

12. A polishing method using a chemical mechanical polishing (CMP) slurry, comprising:
providing a polishing-target film of the wafer positioned;
providing to the polishing pad a slurry containing an abrasive dispersed in deionized water and an organic viscosity modifier added to adjust a viscosity of the slurry to within a range of 0.5 to 3.2 cps; and
polishing the polishing-target film with the polishing pad.

13. The method according to claim 12, wherein the polishing-target film includes one of: an oxide film or a polycrystalline silicon film.

14. The method according to claim 12, wherein the viscosity modifier is a fatty acid ester containing a polyhydric alcohol.

15. The method according to claim 14, wherein the fatty acid ester contains glycerol.

16. The method according to claim 12, wherein the viscosity modifier is a fatty acid ester including polyoxyethylene sorbitan.

17. The method according to claim 12, wherein the abrasive includes ceria (CeO₂) abrasive particles.

18. The method according to claim 12, wherein the abrasive includes one of: alumina (Al₂O₃) abrasive particles, fumed alumina abrasive particles, or both.

19. The method according to claim 12, wherein the viscosity modifier is added in an amount of up to 10 wt % relative to the weight of the slurry.

20. The method according to claim 12, wherein the viscosity modifier is added in an amount such that the viscosity of the slurry is adjusted to at least 1.2 cps.

21. The method according to claim 12, wherein the viscosity modifier is added in an amount such that the viscosity of the slurry is adjusted to within a range of 1.2 to 2.2 cps.

21. The method according to claim 12, wherein the viscosity modifier is added in an amount such that the viscosity of the slurry is adjusted to within a range of 1.4 to 2.2 cps.

22. The method according to claim 12, wherein the viscosity modifier is added in an amount such that the viscosity of the slurry is adjusted to approximately 1.7 cps.

23. A polishing method using a chemical mechanical polishing slurry, comprising:
forming a silicon nitride layer over a semiconductor substrate, the silicon nitride layer exposing a portion of the semiconductor substrate;
etching the exposed portion of the semiconductor substrate to form a trench;
filling the trench with a silicon oxide film;
polishing the silicon oxide film to expose a surface of the silicon nitride layer using a polishing pad a slurry containing an abrasive dispersed in deionized water and an organic viscosity modifier added to adjust the viscosity of the slurry to within a range of 0.5 to 3.2 cps.

24. The method according to claim 23, wherein the viscosity modifier is a fatty acid ester containing a polyhydric alcohol.

25. The method according to claim 24, wherein the fatty acid ester contains glycerol.

26. The method according to claim 23, wherein the viscosity modifier is a fatty acid ester including polyoxyethylene sorbitan.

27. The method according to claim 23, wherein the abrasive includes ceria (CeO₂) abrasive particles.

28. The method according to claim 23, wherein the abrasive includes one of: alumina (Al₂O₃) abrasive particles, fumed alumina abrasive particles, or both.

29. The method according to claim 23, wherein the viscosity modifier is added in an amount of up to 10 wt % relative to the weight of the slurry.

30. The method according to claim 23, wherein the viscosity modifier is added in an amount such that the viscosity of the slurry is adjusted to at least 1.21 cps.

31. The method according to claim 23, wherein the viscosity modifier is added in an amount such that the viscosity of the slurry is adjusted to within a range of 1.21 to 2.14 cps.

32. The method according to claim 23, wherein the viscosity modifier is added in an amount such that the viscosity of the slurry is adjusted to within a range of 1.43 to 2.14 cps.

33. The method according to claim 23, wherein the viscosity modifier is added in an amount such that the viscosity of the slurry is adjusted to approximately 1.72 cps.

34. A polishing method using a chemical mechanical polishing slurry, comprising:
forming a gate stack over a semiconductor substrate;
forming a dielectric layer over the the semiconductor substrate;
forming a mask pattern to expose a portion of the dielectric layer;
etching the dielectric layer to form a landing lug contact hole using the mask pattern;
filling the landing plug contact hole with a conductive layer;
polishing the conductive layer to expose a surface of the gate stack using a polishing pad a slurry containing an abrasive dispersed in deionized water and an organic viscosity modifier added to adjust the viscosity of the slurry to within a range of 0.5 to 3.2 cps.

35. The method according to claim 34, wherein the conductive layer includes a polycrystalline silicon layer.

36. The method according to claim 34, wherein the viscosity modifier is a fatty acid ester containing a polyhydric alcohol.

37. The method according to claim 36, wherein the fatty acid ester contains glycerol.

38. The method according to claim 34, wherein the viscosity modifier is a fatty acid ester including polyoxyethylene sorbitan.

39. The method according to claim 34, wherein the abrasive includes ceria (CeO₂) abrasive particles.

40. The method according to claim 34, wherein the abrasive includes one of: alumina (Al₂O₃) abrasive particles, fumed alumina abrasive particles, or both.

41. The method according to claim 34, wherein the viscosity modifier is added in an amount of up to 10 wt % relative to the weight of the slurry.
